(19) United States
(12) Patent Application Publication
(10) Pub. No.: US 2014/0175475 A1
(43) Pub. Date: Jun. 26, 2014

(54) LIGHT EMITTING DEVICE AND METHOD FOR MANUFACTURING SAME

(71) Applicant: Kabushiki Kaisha Toshiba, Tokyo (JP)

(72) Inventors: Chisato Furukawa, Fukuoka-ken (JP); Takafumi Nakamura, Fukuoka-ken (JP)

(73) Assignee: KABUSHIKI KAISHA TOSHIBA, Tokyo (JP)

(21) Appl. No.: 14/189,873

(22) Filed: Feb. 25, 2014

Related U.S. Application Data
(62) Division of application No. 12/485,106, filed on Jun. 16, 2009.

(30) Foreign Application Priority Data
Oct. 6, 2008 (JP) 2008-259481

(51) Int. Cl. H01L 33/30; H01L 33/40

(52) U.S. Cl. CPC H01L 33/30; H01L 33/40
USPC 257/94

(57) ABSTRACT

A light emitting device and a method for manufacturing the same are provided. The light emitting device includes: a first substrate having electrical conductivity; a foundation layer; a bonded metal layer configured to bond one major surface of the foundation layer to the first substrate; a mask layer provided on the other major surface of the foundation layer, having a window, and made of an insulator; and a multilayer body selectively provided on the foundation layer exposed to the window, and including a light emitting layer.

### CROSS-REFERENCE TO RELATED APPLICATIONS

This application is based upon and claims the benefits of priority from the prior Japanese Patent Application No. 2008-259481, filed on Oct. 6, 2008; the entire contents of which are incorporated herein by reference.

### BACKGROUND OF THE INVENTION

1. Field of the Invention

This invention relates to a light emitting device and a method for manufacturing the same.

2. Background Art

Light emitting devices used for illumination lamps, display devices, car stop lights and tail lights, and traffic signals require high brightness.

In the case where a quaternary semiconductor such as InAlGaP is used to emit light in the visible to infrared wavelength range, a GaAs substrate has a problem of high optical absorption, which decreases brightness.

In this context, using a translucent substrate such as GaP or providing a reflecting layer between the light emitting layer and the substrate allows optical absorption in the substrate to be reduced to facilitate increasing brightness.

Increasing brightness is further facilitated by increasing light extraction efficiency on the upper or lateral side of the chip. For example, a transparent electrode such as ITO (indium tin oxide) can be provided on the chip surface. However, the transparent electrode such as ITO has a problem of low optical transmittance and difficulty in achieving good ohmic contact.

JP-A-2002-164574 (Kokai) discloses a technique related to a high-output light emitting element with improved external quantum efficiency. In this technique, a light extraction window shaped like an elongated rectangle as viewed from above the element is formed by etching. And aside face of the light emitting portion is exposed in a recess formed by etching, which improves external light extraction efficiency.

However, in this technique, the recess needs to be etched to a position deeper than the light emitting layer, which complicates the manufacturing process. Furthermore, as the exposed side face is degraded, it becomes difficult to achieve sufficient reliability.

### SUMMARY OF THE INVENTION

According to an aspect of the invention, there is provided a light emitting device including: a first substrate having electrical conductivity; a foundation layer; a bonded metal layer configured to bond one major surface of the foundation layer to the first substrate; a mask layer provided on the other major surface of the foundation layer, having a window, and made of an insulator; and a multilayer body selectively provided on the foundation layer exposed to the window, and including a light emitting layer.

According to another aspect of the invention, there is provided a light emitting device including: a first substrate having electrical conductivity; a foundation layer; a bonded metal layer configured to bond one major surface of the foundation layer to the first substrate; a mask layer provided on the other major surface of the foundation layer, having a window, and made of an insulator; a multilayer body selectively provided on the foundation layer exposed to the window, and made of an epitaxial film including a light emitting layer; and a lateral growth film provided on the mask layer except the window and made of a non-epitaxial film.

According to another aspect of the invention, there is provided a method for manufacturing a light emitting device, the light emitting device including: a first substrate having electrical conductivity; a foundation layer; a bonded metal layer configured to bond one major surface of the foundation layer to the first substrate; a mask layer provided on the other major surface of the foundation layer, having, a window, and made of an insulator; and a multilayer body selectively provided on the foundation layer exposed to the window, and including a light emitting layer, the method comprising: forming a first metal layer on the first substrate; forming the foundation layer made of a semiconductor on a second substrate; forming a second metal layer on the one major surface of the foundation layer; bonding the first metal layer and the second metal layer to form the bonded metal layer, removing the second substrate to expose the other major surface of the foundation layer; forming the mask layer having the window on the other major surface; and crystal-growing the multilayer body on the foundation layer exposed to the window.

### BRIEF DESCRIPTION OF THE DRAWINGS

FIGS. 1A and 1B are schematic views of a light emitting device according to a first embodiment of the invention;

FIGS. 2A to 3F are process cross-sectional views of the light emitting device according to the first embodiment;

FIGS. 4A and 4B illustrate the emission intensity of a light emitting device according to a comparative example;

FIG. 5 shows a variation of the light emitting device according to the first embodiment; and

FIGS. 6A and 6B are schematic views showing a light emitting device according to a second embodiment.

### DETAILED DESCRIPTION OF THE INVENTION

Embodiments of the invention will now be described with reference to the drawings.

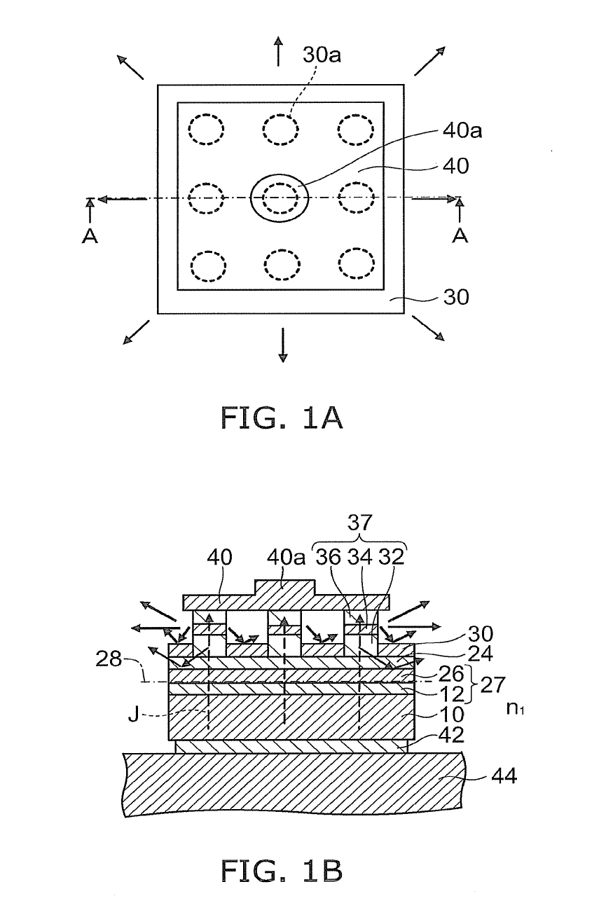

FIGS. 1A and 1B are schematic views of a light emitting device according to a first embodiment of the invention. More specifically, FIG. 1A is a plan view, and FIG. 1B is a cross-sectional view taken along line A-A.

The light emitting device includes a first substrate 10, a foundation layer 24, a bonded metal layer 27 for bonding one major surface of the foundation layer 24 to the first substrate 10, a mask layer 30 provided on the other major surface of the foundation layer 24 and having a window 30a, and a multilayer body 37 which is crystal-grown on the foundation layer 24 exposed to the window 30a and has a light emitting layer 34.

A first metal layer 12 formed on the first substrate 10 and a second metal layer 26 formed on the foundation layer 24 are bonded together at a bonding interface 28 to constitute the bonded metal layer 27.

The multilayer body 37 is formed by crystal-growing a p-type cladding layer 32 made of InAlP (thickness 0.7 μm, carrier concentration 4×10¹⁷ cm⁻³), a light emitting layer 34 made of In_{0.5}(GaₓAl₁₋ₓ)_{0.5}P (0≦x≦1), an n-type cladding layer 36 made of InAlP (thickness 0.6 μm, carrier concentration 4×10¹⁷ cm⁻³) and the like in this order on the foundation layer 24 exposed to the window 30a.

The composition of the light emitting layer 34 is not limited thereto, but may be any of those represented by composition formulas Inₓ(Ga_{y}Al_{1-y})₁₋ₓP (0≦x≦1, 0≦y≦1) and GaₓIn₁₋ₓN_{y}As_{1-y} (0≦x≦1, 0≦y≦1), or a MQW structure composed thereof. This light emitting layer 34 can emit light in the visible to infrared wavelength range.

An n-side electrode 40 is formed on the multilayer body 37, and a p-side electrode 42 is formed on the backside of the first substrate 10. The p-side electrode 42 is bonded to a lead 44 using a silver paste, for example. The chip is enclosed illustratively with a silicone resin having a refractive index n₁ (generally 1.4).

The current J from the p-side electrode 42 to the n-side electrode 40 flows along a route through the first substrate 10, the bonded metal layer 27, the foundation layer 24, and the multilayer body 37. From the multilayer body 37 divided into nine portions, emission light is emitted to the upward, lateral and other directions. Here, the emission light can be reflected upward and laterally at the interface between the foundation layer 24 and the second metal layer 26, which facilitates increasing light extraction efficiency.

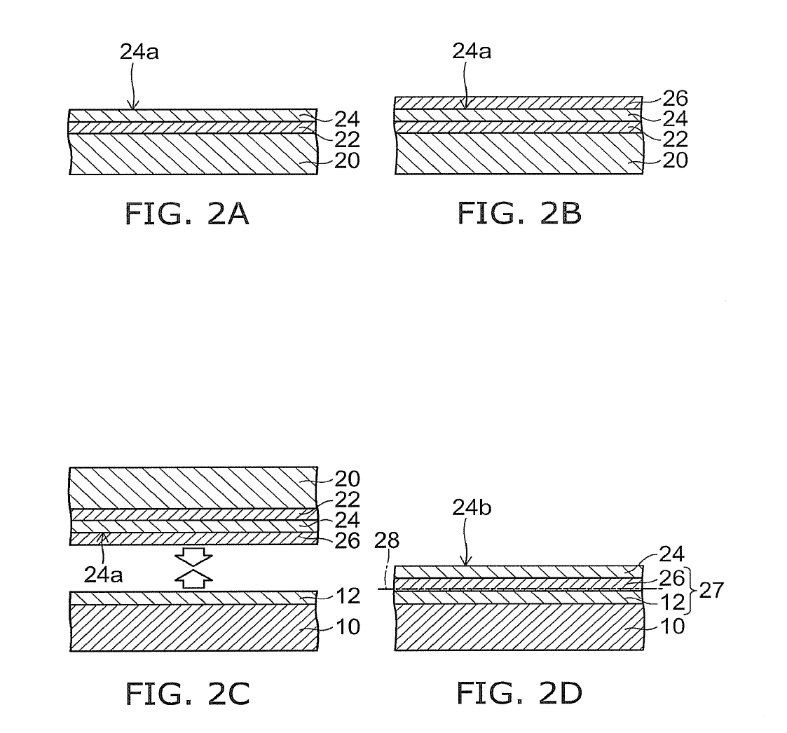

FIGS. 2A to 3F are process cross-sectional views of the light emitting device according to the first embodiment. More specifically, FIGS. 2A to 2D show the process in the wafer state until bonding the substrate, and FIGS. 3A to 3F show the process including crystal growth and electrode formation for one chip.

As shown in FIG. 2A, a buffer layer 22 (thickness 0.5 μm) made of p-type GaAs and a foundation layer 24 (thickness 0.5 μm) illustratively made of InGaAs, InGaP, or InGaAlP are formed on a second substrate 20 illustratively made of p-type GaAs by MOCVD (metal organic chemical vapor deposition) or MBE (molecular beam epitaxy). Furthermore, as shown in FIG. 2B, a second metal layer 26 is formed on one major surface 24a of the foundation layer 24.

On the other hand, as shown in FIG. 2C, a first metal layer 12 is formed on a first substrate 10 illustratively made of p-type Si having electrical conductivity. The first and second metal layer 12 and 26 are made of metals which are chemically stable at high temperatures under the crystal growth condition. Such metals illustratively include Ti, Pt, Hf, W, V, and Mo. The first metal layer 12 and the second metal layer 26 may be made of different metals. The first substrate 10 may be made of any one of Ge, SiC, GaN, and GaP.

The first metal layer 12 and the second metal layer 26 are opposed and laminated to each other and bonded together illustratively by compression bonding to constitute a bonded metal layer 27. Subsequently, the second substrate 20 and the buffer layer 22 are removed illustratively by wet etching. As shown in FIG. 2D, this results in a foundation substrate for regrowth, bonded at the bonding interface 28. Here, bonding in a vacuum atmosphere facilitates avoiding voids.

The foundation layer 24 serving as a regrowth seed layer often contains In, which is likely to cause composition nonuniformity due to aggregation, Al, which is susceptible to oxidation, and P, which has high vapor pressure. Thus, if GaAs is formed on the other major surface 24b of the foundation layer 24 to a thickness of 70 nm or less, the surface of the foundation layer 24 is kept stable at the beginning of regrowth, which facilitates growing a multilayer body 37 having good crystallinity. That is, preferably, a GaAs layer of 70 nm or less is provided between the buffer layer 22 and the foundation layer 24 in the step of forming a foundation substrate shown in FIGS. 2A to 2D.

Subsequently, as shown in FIG. 3A, a mask layer 30 is formed on the other major surface 24b of the foundation layer 24. The mask layer 30 can be made of an insulating film such as SiO₂, SiₓN_{y}, and AlN.

Here, a window 30a is formed in the mask layer 30 by photolithography.

Subsequently, crystal growth of a multilayer body 37 illustratively made of Inₓ(Ga_{y}Al_{1-y})₁₋ₓP (0≦x≦1, 0≦y≦1) is performed using MBE or MOCVD. Here, by using a crystal growth condition capable of suppressing lateral growth on the mask layer 30, the multilayer body 37 can be selectively crystal-grown on the other major surface 24b of the foundation layer 24 exposed to the window 30a as shown in FIG. 3C. The multilayer body 37 includes at least a p-type cladding layer 32, a light emitting layer 34, and an n-type cladding layer 36 layered in this order. Furthermore, a current diffusion layer, a contact layer and the like can be provided between the n-type cladding layer 36 and the n-side electrode 40.

Crystal growth temperature in MOCVD is illustratively 700° C. or more. On the other hand, crystal growth temperature in MBE is lower than 700° C. and can illustratively be in the range from 500 to 650° C. Crystal growth at a temperature lower than 700° C. facilitates reducing stress due to linear expansion coefficient difference between the metal bonding layer 27 and the multilayer body 37. This facilitates enhancing crystallinity and reliability.

Subsequently, as shown in FIG. 3D, the upper portion of the multilayer body 37 is uniformly coated with a polyimide resin 38 by using a spin coat method, for example, so that the upper portion of the multilayer body 37 is exposed after curing.

Furthermore, an n-side electrode 40 capable of forming ohmic contact with the multilayer body 37 is formed as shown in FIG. 3E, and the polyimide resin 38 is removed illustratively by wet etching or CDE (chemical dry etching) as shown in FIG. 3F. Here, it is easy to select an etching condition under which the polyimide resin 38 can be selectively removed while suppressing processing damage to the side surface of the already formed light emitting layer 34. Preferably, the n-side electrode 40 is illustratively circularly thickened in the vicinity of its center to provide a bonding region 40a.

A p-side electrode 42 is formed on the backside of the first substrate 10. Subsequently, by sintering, for example, ohmic contact is formed between the n-side electrode 40 and the multilayer body 37 and between the p-side electrode 42 and the first substrate 10. Subsequently, the wafer is divided into chips illustratively by dicing.

The p-side electrode 42 of the chip is mounted on a lead frame using a silver paste, for example, and the n-side electrode 40 is electrically connected to the lead frame by a bonding wire. The lead frame is embedded in a molded body having a recess, and the chip is exposed to the bottom of the recess. A sealing resin such as silicone is filled in the recess, and cured. Then, light emitting devices are separated by lead cutting. Thus, the light emitting device of FIGS. 1A and 1B is completed. Here, the gap between the n-side electrode 40 and the mask layer 30 is filled with the sealing resin, which can increase the efficiency of light extraction from the light emitting layer 34. Furthermore, the chip with the polyimide resin 38 being left as shown in FIG. 3E can be enclosed with a sealing resin. In this case, light extraction efficiency can be further increased if the refractive index of the polyimide resin 38 is between the refractive index of the sealing resin and the refractive index of the semiconductor.

In this embodiment, the substrate is made of Si, which has high hardness and facilitates avoiding cracking and chipping in the wafer process. Thus, it is possible to increase wafer diameter and production scale, consequently facilitating cost reduction. Furthermore, use of Si, which has high hardness, allows the thickness of the chip to be decreased, and hence facilitates producing a low-profile light emitting device.

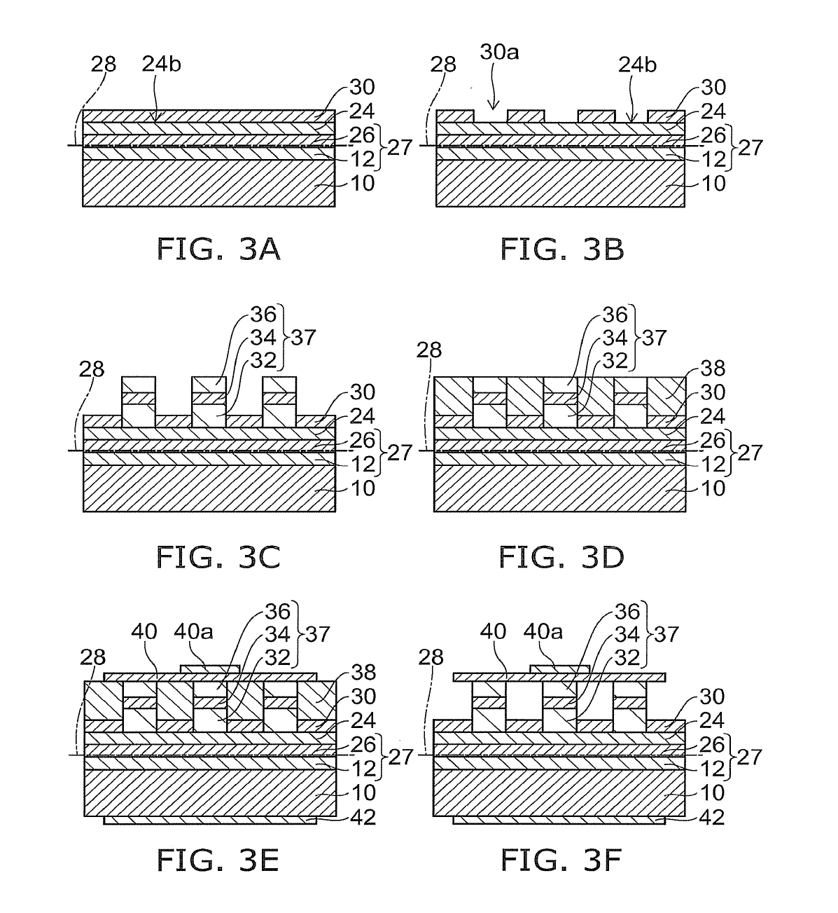

FIGS. 4A and 4B illustrate the emission intensity of a light emitting device according to a comparative example. More specifically, FIG. 4A is a graph showing NFP, and FIG. 4B is a schematic cross-sectional view of the light emitting device.

A p-type cladding layer 114, a light emitting layer 116, an n-type cladding layer 118, and a current diffusion layer 120 are formed in this order on a p-type GaP substrate 110.

The current diffusion layer 120a between thin wire electrodes 142a and 142b having a width of several μm and the current diffusion layer 120a between a bonding electrode 140 and the thin wire electrode 142a have an n-type carrier concentration of as high as e.g. 1.5×10¹⁸ cm⁻³, and include many crystal defects. Hence, emission light directed upward from the light emitting layer 116 is significantly absorbed. Furthermore, if the chip is enclosed with a sealing resin 152 illustratively made of silicone having a refractive index n₁ of generally 1.4, the critical angle θ_{C1} is generally 26 degrees, which makes it impossible to externally extract light having an incident angle equal to or larger than the critical angle θ_{C1}.

Hence, as shown in FIG. 4A, the relative emission intensity of NFP (near field pattern) in the vicinity of the chip surface may decrease to around zero in the vicinity of the center of the region 120a. Thus, in the comparative example, it is difficult to achieve high brightness.

In contrast, in this embodiment, optical absorption can be reduced because no current diffusion layer exists on the lateral side of the light emitting layer 34. Furthermore, although the side surface of the light emitting layer 34 is directly adjacent to the sealing resin having a refractive index n₁ which is lower than that of the semiconductor, the incident angle with respect to the sealing resin can be decreased, which facilitates reducing total reflection. Furthermore, the bonded metal layer 27 can reflect upward the emission light from the light emitting layer 34, which further facilitates increasing light extraction efficiency.

Thus, the light extraction efficiency of this embodiment can be readily increased to 130% or more of the light extraction efficiency of the comparative example. If the mask layer 30 is a high-reflection film illustratively made of an insulator multilayer film, light from the light emitting layer 34 can be reflected upward in the non-forming region of the window 30a, which facilitates further increasing light extraction efficiency.

In a structure where the light emitting layer 34 is exposed to the inner side surface of a recess formed in the wafer, use of dry etching such as RIE (reactive ion etching) leaves processing damage to the exposed surface, which may decrease brightness, ESD (electrostatic discharge) withstand capability, and lifetime. If wet etching is used instead of dry etching, etching often fails to be isotropic and produces crystal defects, which may decrease brightness and lifetime. In contrast, in the first embodiment, there is no etching damage after the selective growth step because the side surface of the light emitting layer 34 has already been formed. This facilitates preventing the decrease of characteristics and reliability.

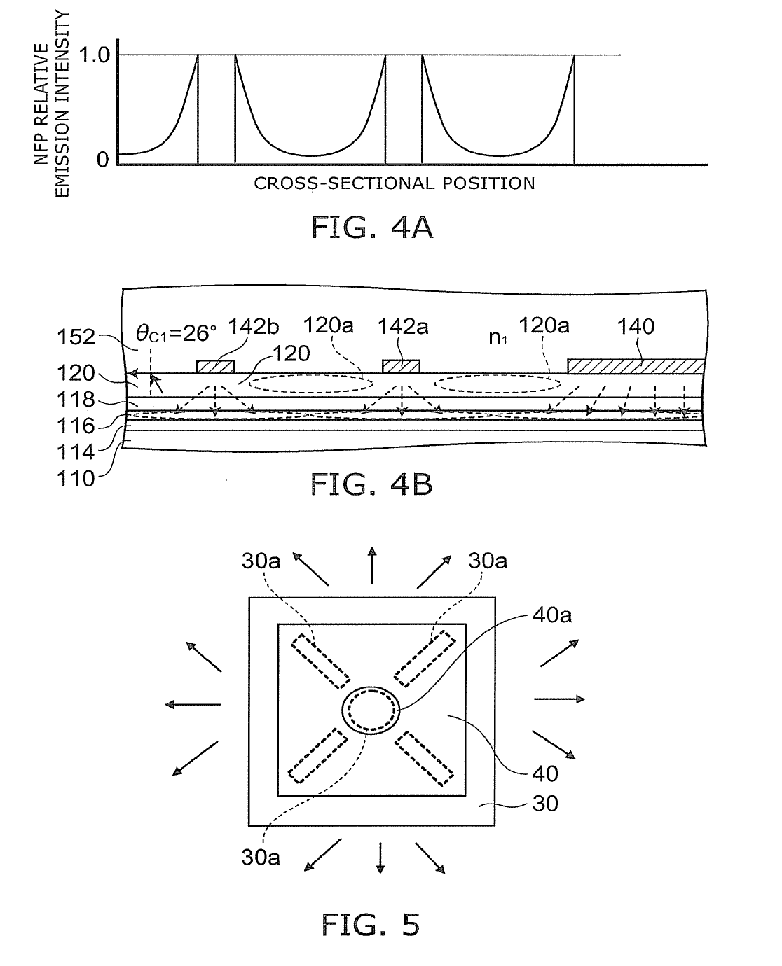

FIG. 5 shows a variation of the light emitting device according to the first embodiment.

The planar shape of the window 30a as viewed from above is not limited to a circle, but may be a rectangle, ellipse, polygon or the like. In this variation, elongated rectangular windows 30a radially extend from a circular window 30a provided at the chip center so as to form an angle of generally 90 degrees with each other. Thus, the multilayer body 37 on the rectangular window 30a can suppress blocking emission light from the light emitting layer 34 on the circular window 30a. Furthermore, the multilayer body 37 formed on the circular window 30a can suppress blocking emission light from the light emitting layer 34 on the rectangular window 30a. This facilitates increasing light extraction efficiency.

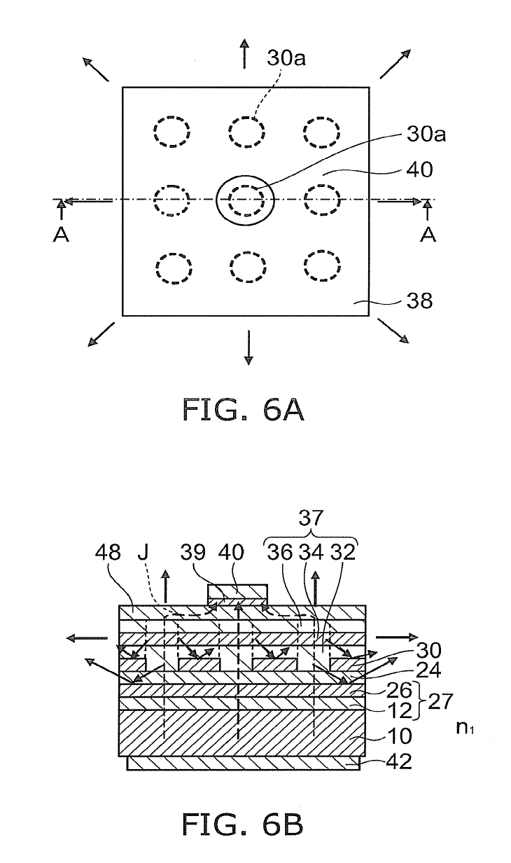

FIGS. 6A and 6B are schematic views showing a light emitting device according to a second embodiment. More specifically, FIG. 6A is a plan view, and FIG. 6B is a cross-sectional view taken along line A-A.

In this embodiment, a multilayer body 37 is formed on the window 30a. Furthermore, also on the window non-forming region of the mask layer 30, a deposition-like growth film due to lateral growth is gradually deposited from the window 30a side. The deposition of this lateral growth film, which is not an epitaxial film, is facilitated illustratively by decreasing the growth temperature, or by decreasing the V/III ratio of the raw material gas. On the other hand, a multilayer body 37 including a light emitting layer 34 and made of an epitaxial film is formed on the window 30a.

In this embodiment, the multilayer body 37 includes a current diffusion layer 48 on the n-type cladding layer 36, and a contact layer 39 on the current diffusion layer 48. Here, decreasing the area of the n-side electrode 40 and the contact layer 39 facilitates enhancing upward emission light. To this end, preferably, a current diffusion layer 48 (thickness 1.5 μm, carrier concentration 1.5×10¹⁸ cm⁻³) made of p-type In_{y}(Ga_{0.3}Al_{0.7})_{1-y}P (0≦y≦1) is provided on the n-type cladding layer 36 to laterally spread injected carriers in the plane of the light emitting layer 34.

More specifically, the current J from the p-side electrode 42 to the n-side electrode 40 flows along a route through the first substrate 10, the bonded metal layer 27, the foundation layer 24, (the recess 30a), the multilayer body 37, the current diffusion layer 48, and the contact layer 39. Thus, from the nine multilayer bodies 37, emission light is emitted to the upward, lateral and other directions. The light directed downward can be reflected upward and laterally by the bonded metal layer 27. Hence, high light extraction efficiency can be achieved. Furthermore, the first substrate 10 may be made of any one of Ge, SiC, GaN, and GaP.

Furthermore, the contact layer 39 made of n-type GaAs provided on the current diffusion layer 48 facilitates forming ohmic contact with the n-side electrode 40. Furthermore, more preferably, the GaAs film is removed outside the immediately underlying region of the n-side electrode 40, because optical absorption can then be reduced.

In this case, the side surface of the light emitting layer 34 is not exposed, which facilitates maintaining reliability at a higher level. Furthermore, the step of forming and processing a polyimide resin can be omitted, which can simplify the manufacturing process.

In the first and second embodiment and the associated variation, the first substrate is of p-type. However, the invention is not limited thereto, but it may be of n-type.

The embodiments of the invention have been described with reference to the drawings. However, the invention is not limited to these embodiments. Those skilled in the art can variously modify the material, size, shape, layout and the like of the substrate, foundation layer, bonded metal layer, mask layer, window, multilayer body, light emitting layer, electrode and the like constituting the embodiments of the invention, and such modifications are also encompassed within the scope of the invention unless they depart from the spirit of the invention.

1-20. (canceled)

21. A light emitting element having selectively provided semiconductor comprising:
a substrate having a first electrical conductivity;
a foundation layer made of semiconductor having the first conductivity;
a bonded metal layer configured to bond one major surface of the foundation layer to the substrate;
a mask layer provided on the other major surface of the foundation layer and made of an insulator, a first window and a second window being provided in the mask layer;
a semiconductor multilayer body having a first region provided on the foundation layer exposed to the first window and a second region provided on the foundation layer exposed to the second window, and made of an epitaxial film including a light emitting layer, the light emitting layer being higher than an upper surface of the mask layer;
a lateral growth film provided on the upper surface of the mask layer; and
a first electrode provided on the first and second regions of the semiconductor multilayer body and the lateral growth film.

22. The element according to claim 21, wherein each window has a planar shape which is one of a circle, a rectangle, an ellipse, and a polygon.

23. The element according to claim 22, wherein the first window includes a center portion and the second window includes a portion with its longitudinal length radially extending from the center portion.

24. The element according to claim 21, wherein the light emitting layer includes one of Inₓ(Ga_{y}Al_{1-y})₁₋ₓP (0≦x≦1, 0≦y≦1) and GaₓIn₁₋ₓN_{y}As_{1-y} (0≦x≦1, 0≦y≦1).

25. The element according to claim 24, wherein the other major surface of the foundation layer is made of a GaAs layer having a thickness of 70 nm or less.

26. The element according to claim 21, wherein
the first substrate is made of silicon, and
the bonded metal layer includes one selected from the group consisting of Ti, Pt, Hf, W, V, and Mo.
